(19) United States
(12) Patent Application Publication
(10) Pub. No.: US 2025/0143149 A1
(43) Pub. Date: May 1, 2025

(54) LIGHT-EMITTING DISPLAY DEVICE AND MANUFACTURING METHOD THEREOF

(71) Applicant: Samsung Display Co., LTD., Yongin-si (KR)

(72) Inventor: Geuntak KIM, Yongin-si (KR)

(21) Appl. No.: 18/753,085

(22) Filed: Jun. 25, 2024

(30) Foreign Application Priority Data
Nov. 1, 2023 (KR) 10-2023-0149043

(51) Int. Cl. H10K 59/80; H10K 50/16; H10K 59/12; H10K 59/122

(52) U.S. Cl. CPC H10K 59/878; H10K 50/166; H10K 59/1201; H10K 59/122

(57) ABSTRACT

A light-emitting display device includes a first electrode, a first electron transport layer disposed on the first electrode, a light-emitting layer disposed on the first electron transport layer, a hole transport layer disposed on the light-emitting layer, a hole injection layer disposed on the hole transport layer, and the hole, and it includes a second electrode disposed on the injection layer, and a reflective member spaced apart from the first electron transport layer, where the reflective member includes an inclined surface which reflects incident light toward the first electron transport layer.

This application claims priority to Korean Patent Application No. 10-2023-0149043, filed on Nov. 1, 2023, the and all the benefits accruing therefrom under 35 U.S.C. § 119, the content of which in its entirety is herein incorporated by reference.

### BACKGROUND

### (a) Field

The disclosure relates to a light-emitting display device and a method of manufacturing the same.

### (b) Description of the Related Art

Unlike bulk materials, the nanoparticles have physical properties (e.g., energy band gap, melting point, etc.), known as intrinsic properties of materials, which may be varied depending on a particle size.

Semiconductor nanocrystals, also referred to as quantum dots, for example, may emit light with a wavelength corresponding to the particle size of the quantum dots upon receiving light energy or electrical energy.

Accordingly, quantum dots may be used as light emitters that emit light with a predetermined wavelength, and these light emitters may be used in display devices.

### SUMMARY

The embodiments of disclosure may provide improved performance of light-emitting display devices.

A light-emitting display device in an embodiment of the disclosure includes a first electrode, a first electron transport layer on the first electrode, a light-emitting layer on the first electron transport layer, a hole transport layer on the light-emitting layer, a hole injection layer on the hole transport layer, and a hole, and it includes a second electrode disposed on the injection layer, and a reflective member spaced apart from the first electron transport layer, where the reflective member includes an inclined surface which reflects incident light toward the first electron transport layer.

In an embodiment, the light-emitting display device may further include an inter-insulating layer disposed below the first electrode and the reflective member.

In an embodiment, the light-emitting display device may further include a protrusion on the inter-insulating layer, where the protrusion may include a first slope, the inclined surface of the reflective member may be disposed on the first slope, and an edge of the inclined surface of the reflective member may coincide with an upper surface of the first electron transport layer.

In an embodiment, the light-emitting display device may further include a protrusion on the inter-insulating layer, where the protrusion may include an upper surface, a first slope, and a second slope, the second slope may be disposed opposite the first slope, and the reflective member may cover the upper surface and the second slope, the inclined surface of the reflective member may be disposed on the first slope, and the edge of the inclined surface of the reflective member may coincide with an upper surface of the first electron transport layer.

In an embodiment, the reflective member may have a higher refractive index than a refractive index of the inter-insulating layer, and an upper surface of the reflective member may coincide with an upper surface of the first electron transport layer.

In an embodiment, the light-emitting display device may further include a second electron transport layer disposed between the first electron transport layer and the light-emitting layer, where the first electron transport layer may include ZnO, and the second electron transport layer may include ZnMgO.

A light-emitting display device in an embodiment of the disclosure includes a first light-emitting device, a second light-emitting device, and a reflective member disposed between the first light-emitting device and the second light-emitting device, where each of the first and second light-emitting devices includes a first electrode, a first electron transport layer on the first electrode, a light-emitting layer on the first electron transport layer, a hole transport layer on the light-emitting layer, a hole injection layer on the hole transport layer, and a second electrode on the hole injection layer, where the reflective member includes a first inclined surface which reflects incident light toward the first electron transport layer of the first light-emitting device, and a second inclined surface which reflects incident light toward the first electron transport layer of the second light-emitting device.

In an embodiment, the first electron transport layer of the first light-emitting device and the first electron transport layer of the second light-emitting device may have different thickness, and a height of an end of the first inclined surface is different from a height of an end of the second inclined surface.

In an embodiment, the end of the first inclined surface of the reflective member may coincide with an upper surface of the first electron transport layer of the first light-emitting device, and the end of the second inclined surface of the reflective member may coincide with an upper surface of the first electron transport layer of the second light-emitting device.

In an embodiment, the light-emitting display device may further include an inter-insulating layer disposed below the first and second light-emitting elements and the reflective member.

In an embodiment, the light-emitting display device may further include a first protrusion and a second protrusion disposed on the inter-insulating layer, where the first inclined surface of the reflective member may be disposed on a first slope of the first protrusion, and the second inclined surface of the reflective member may be disposed on a second slope of the second protrusion.

In an embodiment, the first protrusion may include an upper surface and a third slope disposed opposite the first slope, the second protrusion may include an upper surface and a fourth slope disposed opposite second slope, and the reflective member may cover the upper surfaces of the first and second protrusions, the third slope, and the fourth slope.

In an embodiment, the reflective member may have a higher refractive index than a refractive index of the inter-insulating layer, and the upper surface of the reflective member may coincide with an upper surface of the first electron transport layer.

In an embodiment, each of the first and second light-emitting devices may further include a second electron transport layer disposed between the first electron transport layer and the light-emitting layer, the first electron transport layer may include ZnO, and the second electron transport layer may include ZnMgO.

In this way, in the embodiment of the disclosure, the performance of the light-emitting display device may be improved.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a schematic plan view of an embodiment of a light-emitting display device according to the disclosure.

FIG. 2 is an exemplary cross-sectional view of the light-emitting display device shown in FIG. 1 taken along line II-II.

FIG. 3 is a schematic cross-sectional view of a reflective member and a protrusion for explaining the operation of a light-emitting display device according to the disclosure.

FIG. 4 to FIG. 7 are schematic cross-sectional views showing an embodiment of a method of manufacturing a light-emitting display device according to the disclosure.

FIG. 8 is a schematic cross-sectional view of an embodiment of a light-emitting display device according to the disclosure.

FIG. 9 is a schematic cross-sectional view of an embodiment of a light-emitting display device according to the disclosure.

FIG. 10 is a schematic cross-sectional view of an embodiment of a light-emitting display device according to the disclosure.

### DETAILED DESCRIPTION

Hereinafter, with reference to the attached drawings, various embodiments of the disclosure will be described in detail so that those skilled in the art may easily implement the disclosure.

The disclosure may be implemented in many different forms and is not limited to the embodiments described herein.

In order to clearly explain the disclosure, parts not related to the description have been omitted, and identical or similar components are given the same reference numerals throughout the specification.

In addition, the size and thickness of each part shown in the drawings are arbitrarily determined for convenience of explanation, so the disclosure is not limited thereto.

In particular, in the drawings, the thickness is enlarged and exaggerated to clearly express various layers and areas and to facilitate explanation.

Additionally, when a part of a layer, membrane, region, or plate is said to be “above” or “on” another part, this includes not only cases where it is “directly above” another part, but also cases where there is another part in between.

Conversely, when a part is said to be “right on top” of another part, it means that there is no other part in between.

In addition, being “above” or “on” a reference portion means being disposed above or below the reference portion, and does not necessarily mean being disposed “above” or “on” it in the direction opposite to gravity.

In addition, throughout the specification, when a part is said to “include” a certain element, this means that it may further include other elements, rather than excluding other elements, unless specifically stated to the contrary.

In addition, throughout the specification, when reference is made to “in a plan view,” this means when the target portion is viewed from above, and when reference is made to “in cross-section,” this means when a cross-section of the target portion is cut vertically and viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

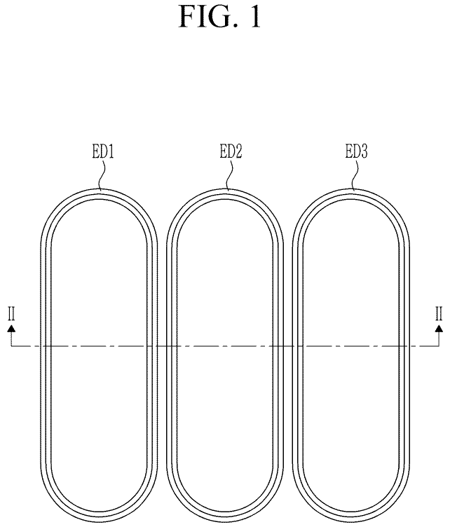

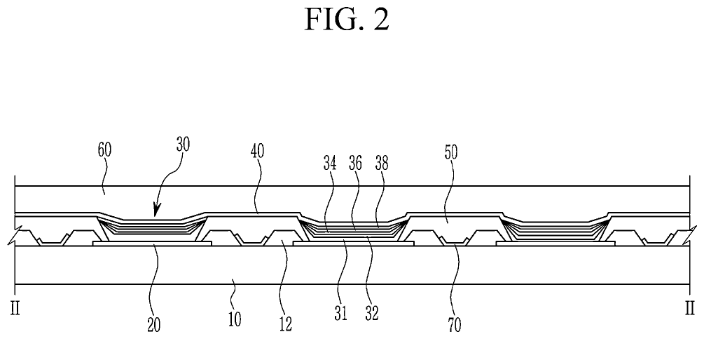

Next, a light-emitting display device in an embodiment of the disclosure will be described in detail with reference to FIGS. 1 and 2.

FIG. 1 is a schematic plan view of an embodiment of a light-emitting display device according to the disclosure, and FIG. 2 is an exemplary cross-sectional view of the light-emitting display device shown in FIG. 1 taken along line II-II.

Referring to FIG. 1, a light-emitting display device in an embodiment of the disclosure may include a plurality of light-emitting elements (or light-emitting devices) ED1, ED2, and ED3.

The light-emitting devices ED1, ED2, and ED3 may include those representing three colors, e.g., a red light-emitting device ED1, a green light-emitting device ED2, and a blue light-emitting device ED3.

The red light-emitting device ED1, the green light-emitting device ED2, and the blue light-emitting device ED3 may be disposed in a row as shown, but their arrangement is not limited thereto.

Referring to FIG. 2, each light-emitting device ED1, ED2, or ED3 may include two electrodes 20 and 40 and a light-emitting laminate 30 interposed therebetween.

The light-emitting laminate 30 may include a first electron transport layer 31, a second electron transport layer 32, a light-emitting layer 34, a hole transport layer 36, and a hole injection layer 38 disposed in order.

This embodiment shows the first and second electron transport layers 31 and 32 disposed at the bottom and the hole transport layer 36 and the hole injection layer 38 disposed at the top, which is also referred to as an inverted structure.

Each light-emitting laminate 30 may be isolated by an insulating layer 50 and, e.g., may be contained in a groove of an insulating layer 50.

Each layer of the light-emitting laminate 30 may be formed by a printing method that may include a series of processes such as printing using ink, drying, and baking.

Each layer formed in this way may be thicker near the side walls of the groove of the insulating layer 50.

The first electron transport layer 31 may include ZnO, and may have reduced defects and enhanced current injection characteristics by irradiating ultraviolet rays.

The thickness of the first electron transport layer 31 may vary depending on the light-emitting device ED1, ED2 or ED3. In an embodiment, the first electron transport layer 31 may be thicker for the red light-emitting device ED1, intermediate for the green light-emitting device ED2, and thinner for the blue light-emitting device ED3, for example.

The second electron transport layer 32 may include ZnMgO.

The first electron transport layer 31 and the second electron transport layer 32 may be integrated into one layer, and in this case, the integrated layer may include ZnMgO.

The light-emitting device ED1, ED2 or ED3 may be disposed on the inter-insulating layer 10, and a pair of protrusions 12 may be disposed between the light-emitting devices on the inter-insulating layer 10.

Each protrusion 12 may include a top surface and both inclined lateral surfaces.

The lateral surface of the protrusion 12 may form an angle of about 20 to about 60 degrees with the upper surface of the inter-insulating layer 10, and the upper surface of the protrusion 12 may be substantially parallel to the upper surface of the inter-insulating layer 10.

One of the two electrodes 20 and 40 may be an anode and the other is a cathode.

The electrode 20 may include a conductor, such as a metal, a conductive metal oxide, or any combinations thereof.

The electrode 20 may include: a metal such as nickel, platinum, vanadium, chromium, copper, zinc, and gold, or their alloy; a conductive metal oxide such as zinc oxide, indium oxide, tin oxide, indium tin oxide (“ITO”), indium zinc oxide (“IZO”), or fluorine-doped tin oxide; or a combination of metal and oxide such as Al and ZnO or Sb and SnO₂, but embodiments of the disclosure may not be limited thereto.

In an embodiment, the electrode 20 may include a transparent conductive metal oxide, such as indium tin oxide (“ITO”).

The electrode 40 may include or consist of a conductor such as a metal, a conductive metal oxide, and/or a conductive polymer.

The electrode 40 may include: a metal such as Al, Mg, Ca, Na, Ka, Ti, In, Y, Li, Gd, Ag, Sn, Pb, Cs, Ba or their alloy, or a multilayered material such as LIF/Al, LiO₂/Al, Liq/Al, LiF/Ca, and BaF₂/Ca, but embodiments of the disclosure may not be limited thereto.

In embodiments, the conductive metal oxide may include those as listed above.

At least one of the two electrodes 20 and 40 may be a light-transmitting electrode, and the light-transmitting electrode may include a conductive metal oxide, e.g., zinc oxide, indium oxide, tin oxide, indium tin oxide (“ITO”), indium zinc oxide (“IZO”), or fluorine doped tin oxide, and may include a single-layered thin film or a multi-layered metal thin film.

When either of the two electrodes 20 and 40 is an opaque electrode, it may include an opaque conductor such as Al, Ag, or Au.

The thickness of the two electrodes 20 and 40 in a thickness direction (e.g., vertical direction in FIG. 2) normal to a main plane extension direction of the inter-insulating layer 10 may not be particularly defined and may be appropriately selected considering device efficiency.

In an embodiment, the thickness of the electrode may be about 5 nanometers (nm) or more, e.g., about 50 nm or more, for example.

In an embodiment, the thickness of the electrode may be about 100 micrometers (μm) or less, such as about 10 μm or less, or about 1 μm or less, about 900 nm or less, about 500 nm or less, or about 100 nm or less, for example. The light-emitting layer 34 includes a plurality of quantum dots.

The quantum dots (hereinafter also referred to as ‘semiconductor nanocrystals’) may include a group II-VI compound, a group III-V compound, a group IV-VI compound, a group IV element or compound, a group I-III-VI compound, a group I-II-IV-VI compound, or any combinations thereof.

The group II-VI compound may be selected from a group including: a binary compound selected from the group consisting of CdSe, CdTe, ZnS, ZnSe, ZnTe, ZnO, HgS, HgSe, HgTe, MgSe, MgS and any combinations thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and any combinations thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and any combinations thereof.

The group II-VI compound may further include a group III metal.

The group III-V compound may be selected from a group including: a binary compound selected from a group consisting of GaN, GaP, GaAs, GaSb, AlN, AlP, AlAs, AlSb, InN, InP, InAs, InSb, and any combinations thereof; a ternary compound selected from a group consisting of GaNP, GaNAs, GaNSb, GaPAs, GaPSb, AlNP, AlNAs, AlNSb, AlPAS, AlPSb, InNP, InNAs, InNSb, InPAs, InPSb, and any combinations thereof; and a quaternary compound selected from a group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and any combinations thereof.

The group III-V compound may further include a group II metal (e.g., InZnP).

The group IV-VI compound may be selected from a group including: a binary compound selected from the group consisting of SnS, SnSe, SnTe, PbS, PbSe, PbTe, and any combinations thereof; a ternary compound selected from the group consisting of SnSeS, SnSeTe, SnSTe, PbSeS, PbSeTe, PbSTe, SnPbS, SnPbSe, SnPbTe, and any combinations thereof; and a quaternary compound selected from the group consisting of SnPbSSe, SnPbSeTe, SnPbSTe, and any combinations thereof.

In embodiments, the group I-III-VI compound may include, but are not limited to, CuInSe₂, CuInS₂, CuInGaSe, and CuInGaS.

In embodiments, the group I-II-IV-VI compound may include, but are not limited to, CuZnSnSe, and CuZnSnS.

The group IV element or compound may be selected from a group including: a single element selected from the group consisting of Si, Ge, and any combinations thereof; and a binary compound selected from the group consisting of SiC, SiGe, and a combination thereof.

In some embodiments of the disclosure, the quantum dots may not include cadmium.

The quantum dots may include a semiconductor nanocrystal based on a group III-V compound including indium and phosphorus.

The group III-V compound may further include zinc.

The quantum dots may include a semiconductor nanocrystal based on a group II-VI compound including a chalcogen element (e.g., S, Se, Te, or combinations thereof) and zinc.

In quantum dots, the above-described binary compound, ternary compound, and/or quaternary compound may be distributed in uniform concentration in a particle, or may be grouped into parts with different concentrations in the same particle.

The semiconductor nanocrystal may have a core/shell structure in which a first semiconductor nanocrystal (core) may be surrounded by a second semiconductor nanocrystal (shell) having a composition the same as or different from the first semiconductor nanocrystal.

In an embodiment, the quantum dots may include a core including InP, InZnP, ZnSe, ZnSeTe, or any combinations thereof, and a shell (or a multi-layered shell) having a different composition from the core and including InP, InZnP, ZnSe, ZnS, ZnSeTe, ZnSeS, or any combinations thereof.

The interface between the core and the shell may have a concentration gradient in which the concentration of elements in the shell decreases toward the center.

Additionally, a semiconductor nanocrystal may have a structure including a single semiconductor nanocrystal core and a multi-layered shell surrounding the core.

At this time, the multi-layered shell may include two or more layers, and each layer may have a single composition, alloy, or gradient concentration composition.

In the quantum dots, the shell material and the core material may have different energy band gaps.

In an embodiment, the energy band gap of the shell material may be larger than that of the core material, for example.

In an alternative embodiment, the energy band gap of the shell material may be smaller than that of the core material.

The quantum dots may include a multilayered shell.

In a multilayered shell, the energy band gap of an outer layer may be larger than that of an inner layer (i.e., a layer closer to the core).

In a multilayered shell, the energy band gap of an outer layer may be smaller than that of an inner layer.

The absorption/emission wavelengths of the quantum dots may be adjusted by changing the composition and size the quantum dots.

The maximum emission peak wavelength of the quantum dots may range from ultraviolet to infrared wavelengths or longer.

In an embodiment, the maximum emission peak wavelength of the quantum dots may be equal to or greater than about 300 nm, such as about 500 nm or more, about 510 nm or more, about 520 nm or more, about 530 nm or more, about 540 nm or more, about 550 nm or more, about 560 nm or more, about 570 nm or more, about 580 nm or more, about 590 nm or more, about 600 nm or more, or about 610 nm or more, for example.

The maximum emission wavelength of the quantum dots may be in a range to about 800 nm or less, such as about 650 nm or less, about 640 nm or less, about 630 nm or less, about 620 nm or less, about 610 nm or less, about 600 nm or less, about 590 nm or less, about 580 nm or less, about 570 nm or less, about 560 nm or less, about 550 nm or less, or about 540 nm or less.

The maximum emission wavelength of the quantum dots may be in a range of from about 500 nm to about 650 nm.

The maximum emission wavelength of the quantum dots may be in a range of from about 500 nm to about 540 nm.

The maximum emission wavelength of quantum dots may be in a range of from about 610 nm to about 640 nm.

The quantum dots may have quantum efficiency of equal to or greater than about 10%, such as about 30% or more, about 50% or more, about 60% or more, about 70% or more, about 90% or more, or even about 100%.

The quantum dots may have a relatively narrow spectrum.

The quantum dots may have a full width at half maximum of the emission wavelength spectrum equal to or less than about 50 nm, for example, such as about 45 nm or less, about 40 nm or less, or about 30 nm or less.

The quantum dots may have a particle size (e.g., a diameter or a length of the longest straight line across the particle) of equal to or greater than about 1 nm and equal to or less than about 100 nm.

The quantum dots may have a particle size of from about 1 nm to about 20 nm, e.g., about 2 nm or more, about 3 nm or more, or about 4 nm or more, and about 50 nm or less, about 40 nm or less, about 30 nm or less, about 20 nm or less, or about 15 nm or less, e.g., about 10 nm or less.

The shape of the quantum dots is not particularly limited.

In an embodiment, the exemplary shapes of the quantum dots may include, but is not limited to, a sphere, polyhedron, pyramid, multipod, square, cuboid, nanotube, nanorod, nanowire, nanosheet, or any combinations thereof, for example.

The quantum dots may be commercially available or appropriately synthesized.

The particle size of the quantum dots may be adjusted relatively freely during colloid synthesis, and the particle size may be uniform.

The quantum dots may include organic ligands having hydrophobic moieties, for example.

Organic ligand moieties may be bound to the surface of quantum dots.

Organic ligands may include RCOOH, RNH2, R2NH, R3N, RSH, R3PO, R3P, ROH, RCOOR, RPO (OH) 2, RHPOOH, R2POOH, or combinations thereof, where each R may be independently a substituted or unsubstituted aliphatic hydrocarbon group from C3 (or C5) to C24 such as C3 (or C5) to C24 alkyl, alkenyl, etc., a substituted or unsubstituted aromatic hydrocarbon group from C6 to C20 such as aryl groups from C6 to C20, etc., or any combinations thereof.

In embodiments, organic ligands may include: thiol compound such as methane thiol, ethane thiol, propane thiol, butane thiol, pentane thiol, hexane thiol, octane thiol, dodecane thiol, hexadecane thiol, octadecane thiol, benzyl thiol, etc.; amine such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributylamine, trioctylamine, etc.; carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, etc.; phosphine compound such as methyl phosphine, ethyl phosphine, propyl phosphine, butyl phosphine, pentyl phosphine, octyl phosphine, dioctyl phosphine, tributyl phosphine, trioctyl phosphine, etc.; phosphine oxide such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, etc.; diphenyl phosphine, triphenyl phosphine compounds or their oxide compounds; C5 to C20 alkyl phosphinic acids, C5 to C20 alkyl phosphonic acids such as hexylphosphinic acid, octylphosphinic acid, dodecanephosphinic acid, tetradecanephosphinic acid, hexadecanephosphinic acid, and octadecanephosphinic acid, but the disclosure is not limited thereto.

The quantum dots may include a hydrophobic organic ligand alone or in a combination thereof.

The hydrophobic organic ligand may not include a photopolymerizable residue, such as an acrylate group or a methacrylate group.

In an embodiment, the light-emitting layer 34 may include a monolayer of quantum dots.

In an alternative embodiment, the light-emitting layer 34 may include one or more monolayers of the quantum dots, e.g., at least two, three, or four monolayers and at most twenty, ten, nine, eight, seven or six monolayers.

The light-emitting layer 34 has a thickness of equal to or greater than about 5 nm, such as about 10 nm or more, about 20 nm or more, or about 30 nm or more and equal to or less than about 200 nm, such as about 150 nm or less, about 100 nm or less, about 90 nm or less, about 80 nm or less, about 70 nm or less, about 60 nm or less, or about 50 nm or less.

The light-emitting layer 34 may have a thickness from about 10 nm to about 150 nm, such as from about 10 nm to about 100 nm, or from about 10 nm to about 50 nm, for example.

The light-emitting layer 34 may have a highest occupied molecular orbital

(“HOMO”) energy level of about 5.4 electronvolts (eV) or more, about 5.6 eV or more, about 5.7 eV or more, about 5.8 eV or more, about 5.9 eV or more, or about 6.0 eV or more.

The HOMO energy level of the emission layer 34 may be about 7.0 eV or less, about 6.8 eV or less, about 6.7 eV or less, about 6.5 eV or less, about 6.3 eV or less, or about 6.2 eV or less.

In an embodiment, the light-emitting layer 34 may have a HOMO energy level of from about 5.6 eV to about 6.0 eV.

The light-emitting layer 34 may have a least unoccupied molecular orbital (“LUMO”) energy level of equal to or less than about 3.8 eV, e.g., about 3.7 eV or less, about 3.6 eV or less, about 3.5 eV or less, about 3.4 eV or less, about 3.3 eV or less, about 3.2 eV or less, or about 3.0 eV or less.

The LUMO energy level of the light-emitting layer 34 may be equal to or higher than about 2.5 eV.

In an embodiment, the light-emitting layer 34 may have an energy band gap of from about 2.4 eV to about 2.9 eV.

A plurality of reflective members 70 may be disposed on the inter-insulating layer 10 and between the light-emitting elements ED1, ED2, and ED3. Each reflective member 70 may be disposed between a pair of adjacent protrusions 12, and may extend to an extent along the inclined lateral surfaces of both the protrusions 12.

The reflective member 70 may include a metal or a relatively low refractive material, e.g., an insulating material having a lower refractive index than a refractive index of the inter-insulating layer 10.

The reflective member 70 may reflect ultraviolet rays when irradiated with the ultraviolet rays, thereby causing thick edge portions of the first electron transport layer 31 to be exposed to the ultraviolet rays.

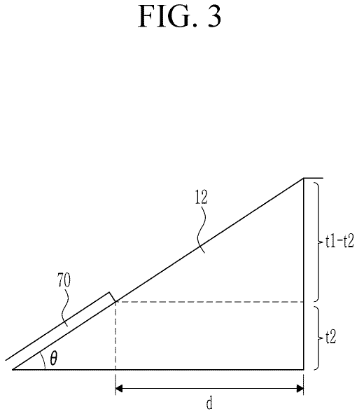

The length of the extension of the reflective member 70 may vary depending on the adjacent light-emitting device, particularly on the thickness of the first electron transport layer 31, which will be described with reference to FIG. 3.

Referring to FIG. 3, when the horizontal distance from the point where the inclined lateral surface (hereinafter referred to as slope) starts from the upper surface of the protrusion 12 to the end of the reflective member 70 is d,

$$d = ( t 1 - t 2 ) / tan θ .$$

Here, t1 denotes the thickness of the protrusion 12, and t2 denotes the (target) thickness of the first electron transport layer 31.

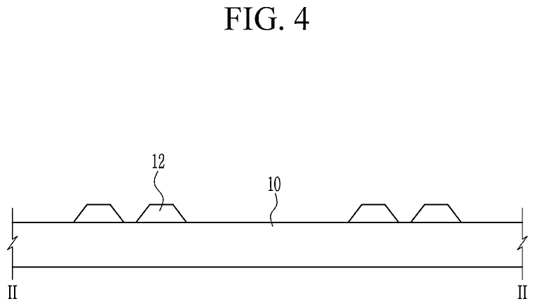

Next, a method of manufacturing a light-emitting display device in an embodiment of the disclosure will be described in detail with reference to FIGS. 4 to 7.

First, referring to FIG. 4, an inter-insulating layer 10 and protrusions 12 thereon may be formed.

The inter-insulating layer 10 and the protrusions 12 may be formed by a single process or from a single layer, but also may be formed by respective processes or from respective layers.

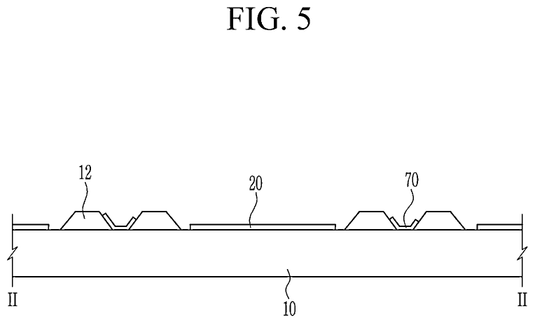

Referring to FIG. 5, electrodes 20 and reflective members 70 may be formed on the inter-insulating layer 10 and the protrusions 12.

The electrodes 20 and the reflective members 70 may be formed by a single process or from a single layer, but also may be formed by respective processes or from respective layers.

The electrodes 20 and the reflective members 70 may include a metal or an organic conductive material.

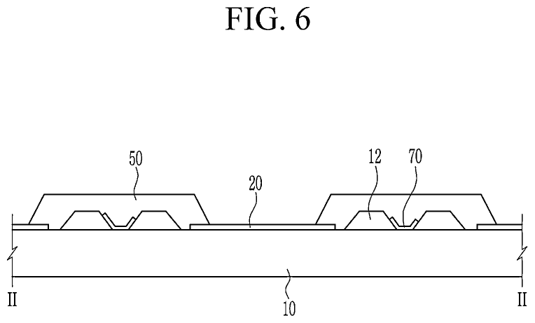

Referring to FIG. 6, an insulating layer 50 may be deposited and patterned such that the electrodes 20 may be exposed.

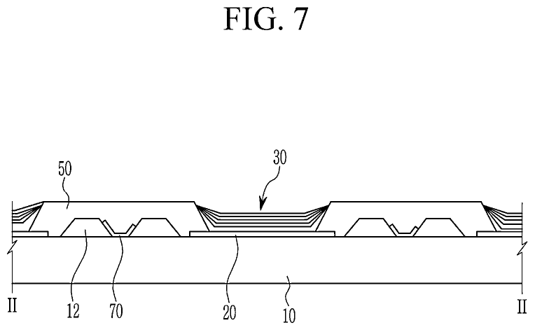

Referring to FIG. 7, light-emitting laminates 30 may be formed on the exposed portions of the electrodes 20 by a printing method including printing, drying, and baking processes.

Referring back to FIG. 2, an electrode 40 may be formed on the light-emitting laminates 30 and the insulating layer 50, and a protective film 60 may be formed on the electrode 40.

Finally, an ultraviolet ray may be irradiated from the side of the inter-insulating layer 10, and the irradiated ultraviolet ray may be reflected by the reflective members 70 to enter onto the thick edges of first electron transport layers 31 of the light-emitting laminates 30.

At this time, the reflective members 70 having proper extension lengths determined as described above may cause only the first electron transport layers 31 of the light-emitting laminate 30 to be exposed to the ultraviolet ray while other parts avoiding the exposure to the ultraviolet ray.

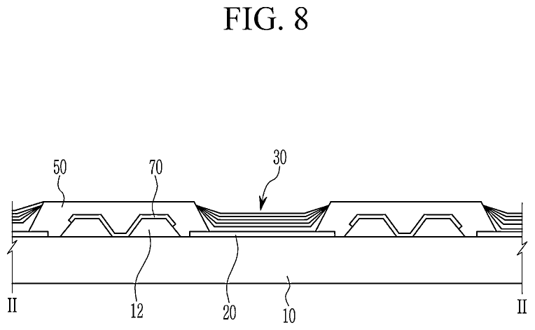

Next, a light-emitting display device in another embodiment of the disclosure will be described in detail with reference to FIG. 8.

FIG. 8 is a schematic cross-sectional view of an embodiment of a light-emitting display device according to the disclosure.

The light-emitting display device shown in FIG. 8 has a structure similar to the light-emitting display device shown in FIG. 2.

However, a reflective member 70 may extend upward along a first slope of a protrusion 12, cover an upper surface of the protrusion 12, and then extend downward to an extent along a second slope of the protrusion 12 disposed opposite the first slope. That is, each reflective member 70 may include an inclined surface.

At this time, the exposed portion of the second slope may be inverse to the exposed portion shown in FIG. 3.

That is, the reflective member 70 may cover a portion corresponding to a horizontal distance d from the upper surface and the remaining portion is exposed.

In this structure, when ultraviolet rays are irradiated, ultraviolet rays reflected from the first slope of the reflective member 70 may be directed to the first electron transport layer 31 after passing through the exposed portion of the second slope, and ultraviolet rays heading in other directions may be blocked by the reflective member 70. That is, an edge of the inclined surface of the reflective member 70 may coincide with an upper surface of the first electron transport layer 31.

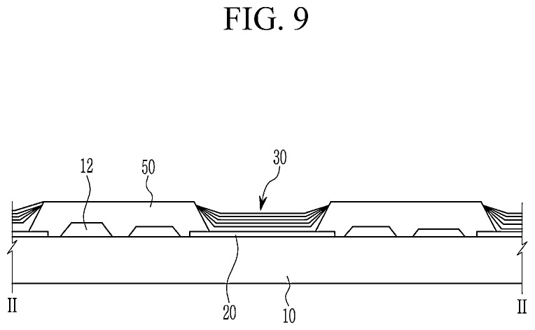

Next, a light-emitting display device in another embodiment of the disclosure will be described in detail with reference to FIG. 9.

FIG. 9 is a schematic cross-sectional view of an embodiment of a light-emitting display device according to the disclosure.

Unlike the light-emitting display device shown in FIG. 2, the light-emitting display device shown in FIG. 9 does not include a separate reflective member.

Instead, the height of a protrusion 12 may be the same as the height of an adjacent first electron transport layer 31, and the protrusion 12 may include a material having a higher refractive index than a refractive index of an inter-insulating layer 10.

In this structure, when ultraviolet rays are irradiated, total reflection may occur on a slope of the protrusion 12, so that only the first electron transport layer 31 may be exposed to the ultraviolet rays, and other layers may be never or less affected by the ultraviolet rays.

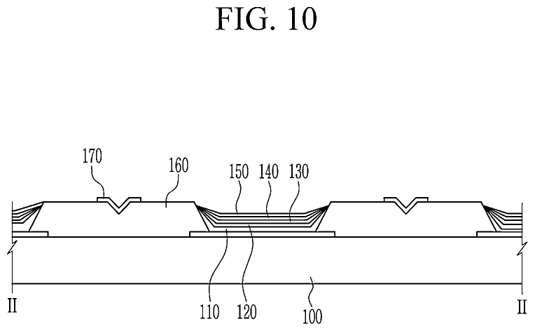

Next, a light-emitting display device in another embodiment of the disclosure will be described in detail with reference to FIG. 10.

FIG. 10 is a schematic cross-sectional view of an embodiment of a light-emitting display device according to the disclosure.

Unlike the previous embodiments, the light-emitting elements of the light-emitting display device shown in FIG. 10 may have a normal (e.g., non-inverted) structure rather than an inverted structure.

That is, a hole injection layer 110, a hole transport layer 120, a light-emitting layer 130, a ZnMgO layer 140, and a ZnO layer 150 may be deposited in sequence from the bottom on an inter-insulating layer 100.

Reflective members 170 may be disposed on an insulating layer 160, but not directly on the inter-insulating layer 100, and may extend along slopes of grooves in the insulating layer 160.

By doing this, only the ZnO layer 150 disposed at the top may be exposed to ultraviolet rays.

Although the embodiments of the disclosure have been described in detail above, the scope of the disclosure is not limited thereto, and various modifications and improvements may be made by those skilled in the art using the basic concepts of the disclosure defined in the following claims.

What is claimed is:

1. A light-emitting display device comprising:
a first electrode;
a first electron transport layer on the first electrode;
a light-emitting layer on the first electron transport layer;
a hole transport layer on the light-emitting layer;
a hole injection layer on the hole transport layer;
a second electrode on the hole injection layer; and
a reflective member spaced apart from the first electron transport layer, the reflective member includes an inclined surface which reflects incident light toward the first electron transport layer.

2. The light-emitting display device of claim 1, further comprising an inter-insulating layer disposed below the first electrode and the reflective member.

3. The light-emitting display device of claim 2, further comprising a protrusion on the inter-insulating layer,
wherein the protrusion incudes a first slope,
the inclined surface of the reflective member is disposed on the first slope, and
an edge of the inclined surface of the reflective member coincides with an upper surface of the first electron transport layer.

4. The light-emitting display device of claim 2, further comprising a protrusion on the inter-insulating layer,
wherein the protrusion includes an upper surface, a first slope, and a second slope,
the second slope is disposed opposite the first slope,
the reflective member covers the upper surface and the second slope,
the inclined surface of the reflective member is disposed on the first slope, and
an edge of the inclined surface of the reflective member coincides with an upper surface of the first electron transport layer.

5. The light-emitting display device of claim 2, wherein
the reflective member has a higher refractive index than a refractive index of the inter-insulating layer, and
an upper surface of the reflective member coincides with an upper surface of the first electron transport layer.

6. The light-emitting display device of claim 1, further comprising a second electron transport layer disposed between the first electron transport layer and the light-emitting layer,
wherein the first electron transport layer comprises ZnO, and
the second electron transport layer comprises ZnMgO.

7. A light-emitting display device comprising:
a first light-emitting element;
a second light-emitting element; and
a reflective member disposed between the first light-emitting element and the second light-emitting element, each of the first and second light-emitting elements comprising:
a first electrode;
a first electron transport layer on the first electrode;
a light-emitting layer on the first electron transport layer;
a hole transport layer on the light-emitting layer;
a hole injection layer on the hole transport layer; and
a second electrode on the hole injection layer, and
the reflective member including:
a first inclined surface which reflects incident light toward the first electron transport layer of the first light-emitting element; and
a second inclined surface which reflects incident light toward the first electron transport layer of the second light-emitting element.

8. The light-emitting display device of claim 7, wherein
the first electron transport layer of the first light-emitting element and the first electron transport layer of the second light-emitting element have different thickness from each other, respectively, and
a height of an end of the first inclined surface is different from a height of an end of the second inclined surface.

9. The light-emitting display device of claim 8, wherein
the end of the first inclined surface of the reflective member coincides with an upper surface of the first electron transport layer of the first light-emitting element, and
the end of the second inclined surface of the reflective member coincides with an upper surface of the first electron transport layer of the second light-emitting element.

10. The light-emitting display device of claim 8, further comprising an inter-insulating layer disposed below the first and second light-emitting elements and the reflective member.

11. The light-emitting display device of claim 10, further comprising a first protrusion and a second protrusion disposed on the inter-insulating layer,
wherein the first inclined surface of the reflective member is disposed on a first slope of the first protrusion, and
the second inclined surface of the reflective member is disposed on a second slope of the second protrusion.

12. The light-emitting display device of claim 11, wherein
the first protrusion includes an upper surface and a third slope disposed opposite the first slope,
the second protrusion includes an upper surface and a fourth slope disposed opposite the second slope, and
the reflective member covers the upper surfaces of the first and second protrusions, the third slope, and the fourth slope.

13. The light-emitting display device of claim 10, wherein
the reflective member has a higher refractive index than a refractive index of the inter-insulating layer, and
a top surface of the reflective member coincides with an upper surface of the first electron transport layer.

14. The light-emitting display device of claim 7, wherein
each of the first and second light-emitting elements further comprises a second electron transport layer disposed between the first electron transport layer and the light-emitting layer,
the first electron transport layer comprises ZnO, and
the second electron transport layer comprises ZnMgO.

15. A method of manufacturing a light-emitting display device, the method comprising:
forming the light-emitting display device comprising a plurality of light-emitting elements and a reflective member spaced apart from the plurality of light-emitting elements, each of the plurality of light-emitting elements comprising a first electrode, a first electron transport layer, a light-emitting layer, a hole transport layer, a hole injection layer, and a second electrode;
irradiating an ultraviolet ray to the light-emitting display device; and
reflecting an irradiated ultraviolet ray toward the first electron transport layer by the reflective member.

16. The method of claim 15, wherein the light-emitting display device further comprises an inter-insulating layer below the first electrode and the reflective member.

17. The method of claim 16, wherein the light-emitting display device further comprises a protrusion on the inter-insulating layer, and
the reflective member includes an inclined surface disposed on a first slope of the protrusion, and an end of the inclined surface of the reflective member coincides with an upper surface of the first electron transport layer.

18. The method of claim 16, wherein
the light-emitting display device further comprises a protrusion on the inter-insulating layer,
the protrusion includes an upper surface, a first slope, and a second slope,
the second slope is disposed opposite the first slope,
the reflective member includes an inclined surface disposed on the first slope of the protrusion, and
an end of the inclined surface of the reflective member coincides with an upper surface of the first electron transport layer.

19. The method of claim 16, wherein
the reflective member has a higher refractive index than a refractive index of the inter-insulating layer, and
an upper surface of the reflective member coincides with an upper surface of the first electron transport layer.

20. The method of claim 15, wherein
the light-emitting display device further comprises a second electron transport layer between the first electron transport layer and the light-emitting layer,
the first electron transport layer comprises ZnO, and
the second electron transport layer comprises ZnMgO.
